(19) United States
(12) Patent Application Publication
(10) Pub. No.: US 2017/0226275 A1
(43) Pub. Date: Aug. 10, 2017

(54) CURABLE COMPOSITIONS

(71) Applicant: BLUE CUBE IP LLC, Midland, MI (US)

(72) Inventors: JOEY W. STORER, MIDLAN, MI (US); JACLYN MURPHY, FREEPORT, TX (US); LAMECK BANDA, FREEPORT, TX (US)

(21) Appl. No.: 15/320,481

(22) PCT Filed: Jun. 17, 2015
(86) PCT No.: PCT/US2015/036148

§ 371 Date: Dec. 20, 2016

Related U.S. Application Data
(60) Provisional application No. 62/017,552, filed on Jun. 26, 2014.

(51) Int. Cl. C08G 59/42; H05K 1/03; H05K 1/02; C08K 3/22; C08J 5/24

(52) U.S. Cl. CPC C08G 59/4261; C08K 3/22; C08J 5/24; H05K 1/024; H05K 1/0373; C08J 2363/00; C08K 2003/2241

(57) ABSTRACT

The instant invention provides a curable composition suitable for electrical laminate applications, and electrical laminates made therefrom. The curable composition suitable for electrical laminate applications according to the present invention comprises a) an epoxy resin; and b) a hardener compound for curing with the epoxy resin; and c) titanium dioxide.

### REFERENCE TO RELATED APPLICATIONS

The present application claims the benefit of U.S. Provisional Application No. 62/017,552, filed Jun. 26, 2014, which is incorporated herein by reference in its entirety.

### FIELD OF DISCLOSURE

The instant invention relates to a curable composition suitable for electrical laminate applications, and electrical laminates made therefrom.

### BACKGROUND

The Printed Circuit Board industry has long trended toward increasing operating frequency. The operating frequencies are moving beyond the megahertz range and into the range of 1-70 gigahertz (GHz). It is commonly known in the industry that there are electrical signal losses that are unique to this high-frequency regime. There are losses due to the natural dissipation factor of the electrical laminate lying at the core of the printed circuit board. There are also losses due to the copper traces themselves and the corresponding roughness of the copper in these signal traces. Additionally, there are signal losses that appear as resonance “dips” that are due to periodically loaded transmission lines. The periodicity arises from a regular pattern inherent to the glass fabric that makes up the electrical laminate structure. Glass fabric is commonly used to add rigidity in combination with an epoxy-type matrix.

The periodicity that can be assigned to the signal loss at specific frequencies is dependent on the weave pattern of the glass fabric in combination with the difference in dielectric constant between the glass and the epoxy matrix. The dielectric constant of the glass fabric is typically at about Dₖ=6.0 but can vary higher or lower as a function of manufacturer and product type. Additionally, the volume fraction glass in a particular printed circuit board can vary as a function of weave type or weave density as well as the final resin content.

Another contributor to the overall dielectric properties of the printed circuit board is the nature of the polymer (thermoset or thermoplastic) that is used to imbibe and bond with the glass fabric. Typically the polymer is a thermoset based on epoxy in combination with a hardener.

Inherent to this system is the tendency to periodically load the circuit transmission lines such that several resonance dips are produced in the range of 5-50 GHz. The intensity of the resonance dips is defined by a Bloch Wave effect expressed in the difference between the dielectric constant of the glass fabric and the polymer (thermoset) matrix. The specific frequencies of these resonance dips are dependent upon the specific periodicity due to the glass fabric and the orientation of the transmission lines (circuits) relative to the pattern in the glass fabric.

Therefore, an electrical laminate which can effectively mitigate the appearance of resonance dips at high frequency without increasing the overall dissipation factor of the system is desired. This is because the selection of operating frequency and the circuit designs associated with operating frequency will not be impaired by the appearance of resonances (signal attenuation) at frequencies inherent to the material and the differential dielectric properties that would otherwise exist between the resin and the glass fabric within the laminate structure.

### SUMMARY

The instant invention provides a curable composition suitable for electrical laminate applications, and electrical laminates made therefrom. In one embodiment, the instant invention provides a curable composition suitable for electrical laminate applications comprising a) an epoxy resin; and

b) a hardener compound for curing with the epoxy resin, the hardener compound comprising:

a terpolymer having a first constitutional unit of the formula (I):

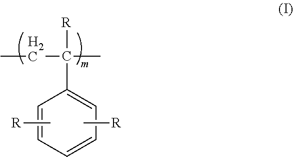

a second constitutional unit of the formula (II):

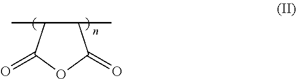

and a third constitutional unit of the formula (III):

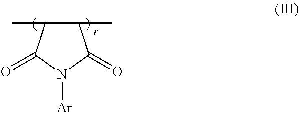

where each m, n and r is independently a real number that represents a mole fraction of the respective constitutional unit in the terpolymer, each R is independently a hydrogen, an aromatic group or an aliphatic group, Ar is an aromatic radical, and where the epoxy group to the second constitutional unit has a molar ratio in a range of 1.0:1.0 to 2.7:1.0; and c) titanium dioxide.

In another alternative embodiment, the instant invention further provides an electrical laminate comprising the inventive curable composition.

### DETAILED DESCRIPTION

For the various embodiments, the curable composition includes an epoxy resin, and a hardener compound for curing with the epoxy resin. For the various embodiments, the hardener compound includes a terpolymer having a first constitutional unit of the formula (I):

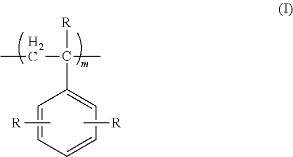

a second constitutional unit of the formula (II):

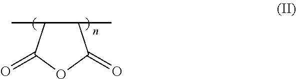

and a third constitutional unit of the formula (III):

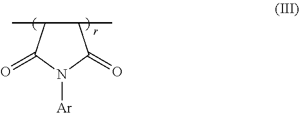

where each m, n and r is independently a real number that represents a mole fraction of the respective constitutional unit in the terpolymer, each R is independently a hydrogen, an aromatic group or an aliphatic group, Ar is an aromatic radical, and where the epoxy group to the second constitutional unit has a molar ratio in a range of 1.0:1.0 to 2.7:1.0, The hardener further comprises titanium dioxide.

In various embodiments, each R is hydrogen and Ar is a phenyl group.

For various embodiments, the mole fraction m is 0.50 or greater and the mole fractions n and r are each independently 0.45 to 0.05, where (m+n +r)=1.00. For various embodiments, the first constitutional unit to the second constitutional unit has a molar ratio in a range of 1:1 to 20:1; for example, the molar ratio of the first constitutional unit to the second constitutional unit can have a range of 3:1 to 15:1.

For various embodiments, the second constitutional unit constitutes 0.1 percent (%) to 41% by weight of the terpolymer. In one embodiment, the second constitutional unit constitutes 5% to 20% by weight of the terpolymer. For various embodiments, the third constitutional unit constitutes 0.1% to 62.69% by weight of the terpolymer. In one embodiment, the third constitutional unit constitutes 0.5% to 50% by weight of the terpolymer.

For the various embodiments, examples of the aromatic group include, but are not limited to, phenyl, biphenyl, naphthyl, substituted phenyl or biphenyl, and naphthyl. Examples of the aliphatic group include, but are not limited to, alkyl and alicyclic alkyl. Examples of the aromatic radical include, but are not limited to, phenyl, biphenyl, naphthyl, substituted phenyl, substituted biphenyl, and substituted naphthyl.

In various embodiments, the terpolymer is a styrene and maleic anhydride (SMA) copolymer that has been modified with an aromatic amine, such as aniline.

In various embodiments, the ratio of styrene to maleic anhydride can be adjusted to alter the properties of a cured product.

For the various embodiments, the styrene and maleic anhydride copolymer is modified to include an aromatic amine compound (e.g., aniline). The aromatic amine compound (e.g., aniline) can be used to react with part of the maleic anhydride groups in the styrene and maleic anhydride copolymer. The modified styrene and maleic anhydride terpolymer can be incorporated into curable compositions. For the various embodiments, the curable compositions of the present disclosure are formed such that the epoxy group to the second constitutional unit of the terpolymer has a molar ratio in a range of 1.0:1.0 to 2.7:1.0, preferably in a range of 1.1:1.0 to 1.9:1.0, and more preferably in a range of 1.3:1.0 to 1.7:1.0. As provided herein, forming the curable composition having the molar ratio of the epoxy group to the second constitutional unit within the range of 1.0:1.0 to 2.7:1.0 provides the cured product having desirable thermal properties and electrical properties. As used herein, “constitutional units” refer to the smallest constitutional unit (a group of atoms comprising a part of the essential structure of a macromolecule), or monomer, the repetition of which constitutes a macromolecule, such as a polymer.

For one or more embodiments, the curable compositions include an epoxy compound. The epoxy compound can be selected from the group consisting of aromatic epoxy compounds, alicyclic epoxy compounds, aliphatic epoxy compounds, and combinations thereof.

For one or more embodiments, the curable compositions include an aromatic epoxy compound. Examples of aromatic epoxy compounds include, but are not limited to, glycidyl ether compounds of polyphenols, such as hydroquinone, resorcinol, bisphenol A, bisphenol F, 4,4′-dihydroxybiphenyl, phenol novolac, cresol novolac, trisphenol (tris-(4-hydroxyphenyl)methane), 1,1,2,2-tetra(4-hydroxyphenyl)ethane, tetrabromobisphenol A, 2,2-bis(4-hydroxyphenyl)-1,1,1,3,3,3-hexafluoropropane, 1,6-dihydroxynaphthalene, and combinations thereof.

For one or more embodiments, the curable compositions include an alicyclic epoxy compound. Examples of alicyclic epoxy compounds include, but are not limited to, polyglycidyl ethers of polyols having at least one alicyclic ring, or compounds including cyclohexene oxide or cyclopentene oxide obtained by epoxidizing compounds including a cyclohexene ring or cyclopentene ring with an oxidizer. Some particular examples include, but are not limited to, hydrogenated bisphenol A diglycidyl ether; 3,4-epoxycyclohexylmethyl-3,4-epoxycyclohexyl carboxylate; 3,4-epoxy-l-methylcyclohexyl-3,4-epoxy-l-methylhexane carboxylate; 6-methyl-3,4-epoxycyclohexylmethyl-6-methyl-3,4-epoxycyclohexane carboxylate; 3,4-epoxy-3-methylcyclohexylmethyl-3,4-epoxy-3-methylcyclohexane carboxylate; 3,4-epoxy-5-methylcyclohexylmethyl-3,4-epoxy-5-methylcyclohexane carboxylate; bis(3,4-epoxycyclohexylmethyl)adipate; methylene-bis(3,4-epoxycyclohexane); 2,2-bis(3,4-epoxycyclohexyl)propane; dicyclopentadiene diepoxide; ethylene-bis(3,4-epoxycyclohexane carboxylate); dioctyl epoxyhexahydrophthalate; di-2-ethylhexyl epoxyhexahydrophthalate; and combinations thereof.

For one or more embodiments, the curable compositions include an aliphatic epoxy compound. Examples of aliphatic epoxy compounds include, but are not limited to, polyglycidyl ethers of aliphatic polyols or alkylene-oxide adducts thereof, polyglycidyl esters of aliphatic long-chain polybasic acids, homopolymers synthesized by vinyl-polymerizing glycidyl acrylate or glycidyl methacrylate, and copolymers synthesized by vinyl-polymerizing glycidyl acrylate or glycidyl methacrylate and other vinyl monomers. Some particular examples include, but are not limited to glycidyl ethers of polyols, such as 1,4-butanediol diglycidyl ether; 1,6-hexanediol diglycidyl ether; a triglycidyl ether of glycerin; a triglycidyl ether of trimethylol propane; a tetraglycidyl ether of sorbitol; a hexaglycidyl ether of dipentaerythritol; a diglycidyl ether of polyethylene glycol; and a diglycidyl ether of polypropylene glycol; polyglycidyl ethers of polyether polyols obtained by adding one type, or two or more types, of alkylene oxide to aliphatic polyols such as propylene glycol, trimethylol propane, and glycerin; diglycidyl esters of aliphatic long-chain dibasic acids; and combinations thereof.

The terpolymer can be obtainable by combining a copolymer with a monomer via chemical reaction, for example, reacting a styrene and maleic anhydride copolymer with the amine compound. Additionally, the terpolymer can be obtainable by combining more than two species of monomer via chemical reaction (e.g., reacting a styrenic compound, maleic anhydride, and the maleimide compounds). The reacted monomers and/or copolymers form constitutional units of the terpolymer.

Styrenic compounds, as used herein, include the compound styrene having the chemical formula C₆H₅CH═CH₂ and compounds derived therefrom (e.g. styrene derivatives), unless explicitly stated otherwise. Maleic anhydride, which may also be referred to as cis-butenedioic anhydride, toxilic anhydride, or dihydro-2,5-dioxofuran, has a chemical formula: C₂H₂(CO)₂O. Commercial examples of such styrene and maleic anhydride copolymer include, but are not limited to, SMA® EF-40, SMA® EF-60 and SMA® EF-80 all of which are available from Sartomer Company, Inc., and SMA® EF-100, which is available from Elf Atochem, Inc.

For the various embodiments, styrene and maleic anhydride copolymers can be reacted with aromatic amine compounds such as aniline to form the terpolymer. For the various embodiments, the styrene and maleic anhydride copolymers have a styrene to maleic anhydride molar ratio of 1:1 to 8:1; for example; the copolymer can have a molar ratio of styrene to maleic anhydride of 3:1 to 6:1.

For various embodiments, the styrene and maleic anhydride copolymer can have a weight average molecular weight from 2,000 to 20,000; for example, the copolymer can have a weight average molecular weight from 3,000 to 11,500. The weight average molecular weight can be determined by gel permeation chromatography (GPC).

For various embodiments, the styrene and maleic anhydride copolymer can have a molecular weight distribution from 1.1 to 6.1; for example, the copolymer can have a molecular weight distribution from 1.2 to 4.0.

For various embodiments, the styrene and maleic anhydride copolymer can have an acid number from 100 milligram potassium hydroxide per gram (mg KOH/g) to 480 mg KOH/g; for example, the copolymer can have an acid number from 120 mg KOH/g to 285 mg KOH/g, or from 156 mg KOH/g to 215 mg KOH/g.

For various embodiments, the styrene and maleic anhydride copolymers are modified with the aromatic amine compound. Specific examples of the aromatic amine compound include, but are not limited to, aniline, substituted aniline, naphthalene amine, substituted naphthalene amine, and combinations thereof. Other aromatic amine compounds are also possible.

As discussed herein, the terpolymers of the present disclosure are obtainable by modifying the styrene and maleic anhydride copolymer with the aromatic amine compound. The process for modifying the styrene and maleic anhydride copolymer can include imidization.

The curable compositions of the present disclosure can incorporate styrene and maleic anhydride copolymers having a styrene to maleic anhydride ratio of 4:1 or greater. For example, the styrene and maleic anhydride copolymer is modified with the amine compound and used in the curable composition such the curable compositions of the present disclosure have a molar ratio of the epoxy group to the second constitution unit within a range of 1.0:1.0 to 2.7:1.0. For various embodiments, the curable compositions of the present disclosure have a molar ratio of the epoxy group to the second constitution unit within a range of 1.1:1.0 to 1.9:1.0, and more preferably within a range of 1.3:1.0 to 1.7:1.0.

The curable composition also contains titanium dioxide. The titanium dioxide is generally present in the curable composition in a range of from 10 weight percent to 50 weight percent. All weight percents between 10 weight percent and 50 weight percent are included herein and disclosed herein; for example, the metal oxide content in the curable composition can be 15 weight percent, 20 weight percent, 30 weight percent, 35 weight percent, 38 weight percent, 40 weight percent, 42 weight percent, 45 weight percent, or 47 weight percent. In an embodiment, the titanium dioxide is in a rutile crystal phase. One commercial example of this is DuPont R-706.

In various embodiments, the curable composition can also contain a coupling agent. A coupling agent is used to provide a stable bond between two otherwise incompatible surfaces. Nonlimiting examples of coupling agents include organofunctional silanes such as XIAMETER® OFS-6040 and XIAMETER® OFS-6016 and polymeric adhesion promoters such as BYK® 4511.

The coupling agent is generally present in the curable composition in a range of from 1 weight percent to 5 weight percent. All weight percents between 1 weight percent and 5 weight percent are included herein and disclosed herein; for example, the coupling agent content in the curable composition can be 1.25 weight percent, 1.5 weight percent, 1.75 weight percent, 1.8 weight percent, 2 weight percent, 2.2 weight percent, 2.5 weight percent, 3 weight percent, 3.5 weight percent or 4 weight percent.

For various embodiments, the curable composition can include a solvent. The solvent can be selected from the group consisting of methyl ethyl ketone (MEK), toluene, xylene, N,N-dimethylformamide (DMF), propylene glycol methyl ether (PM), cyclohexanone, propylene glycol methyl ether acetate (DOWANOL™ PMA), and mixtures therefore. For various embodiments, the solvent can be used in an amount of from 30% to 60% by weight based on a total weight of the curable composition. For various embodiments, the curable compositions can include a catalyst. Examples of the catalyst include, but are not limited to, 2-methyl imidazole (2MI), 2-phenyl imidazole (2PI), 2-ethyl-4-methyl imidazole (2E4MI), 1-benzyl-2-phenylimidazole (1B2PZ), boric acid, triphenylphosphine (TPP), tetraphenylphosphonium-tetraphenylborate (TPP-k) and combinations thereof. For the various embodiments, the catalyst (10% solution by weight) can be used in an amount of from 0.01% to 2.0% by weight based on solid component weight in curable composition.

For various embodiments, the curable compositions can include a co-curing agent. The co-curing agents can be reactive to the epoxide groups of the epoxy compounds. The co-curing agent can be selected from the group consisting of novolacs, amines, anhydrides, carboxylic acids, phenols, thiols, and combinations thereof. For the various embodiments, the co-curing agent can be used in an amount of from 1% to 90% by weight based on a weight of the terpolymer.

To prepare the curable composition, the epoxy resin is reacted with the terpolymer described above to form an epoxy/hardener admixture. The titanium dioxide component can then be incorporated into the epoxy/hardener admixture by any suitable method. In an embodiment, the titanium dioxide is incorporated into the epoxy/hardener admixture by high shear mixing. Optionally, dispersing agents can be used.

For one or more embodiments, the curable compositions include an additive. The additive can be selected from the group consisting of dyes, pigments, colorants, antioxidants, heat stabilizers, light stabilizers, plasticizers, lubricants, flow modifiers drip retardants, flame retardants, antiblocking agents, mold release agents, toughening agents, low-profile additives, stress-relief additives, and combination thereof. The additive can be employed in an effective amount for a particular application, as is understood by one having ordinary skill in the art. For different applications, the effective amount can have different values. Embodiments of the present disclosure provide prepregs that includes a reinforcement component and the curable composition, as discussed herein. The prepreg can be obtained by a process that includes impregnating a matrix component into the reinforcement component. The matrix component surrounds and/or supports the reinforcement component. The disclosed curable compositions can be used for the matrix component. The matrix component and the reinforcement component of the prepreg provide a synergism. This synergism provides that the prepregs and/or products obtained by curing the prepregs have mechanical and/or physical properties that are unattainable with only the individual components.

The reinforcement component can be a fiber. Examples of fibers include, but are not limited to, glass, aramid, carbon, polyester, polyethylene, quartz, metal, ceramic, biomass, and combinations thereof. The fibers can be coated. An example of a fiber coating includes, but is not limited to, boron.

Examples of glass fibers include, but are not limited to, A-glass fibers, E-glass fibers, C-glass fibers, R-glass fibers, S-glass fibers, T-glass fibers, and combinations thereof. Aramids are organic polymers, examples of which include, but are not limited to, Kevlar®, Twaron®, and combinations thereof. Examples of carbon fibers include, but are not limited to, those fibers formed from polyacrylonitrile, pitch, rayon, cellulose, and combinations thereof. Examples of metal fibers include, but are not limited to, stainless steel, chromium, nickel, platinum, titanium, copper, aluminum, beryllium, tungsten, and combinations thereof. Examples of ceramic fibers include, but are not limited to, those fibers formed from aluminum oxide, silicon dioxide, zirconium dioxide, silicon nitride, silicon carbide, boron carbide, boron nitride, silicon boride, and combinations thereof. Examples of biomass fibers include, but are not limited to, those fibers formed from wood, non-wood, and combinations thereof.

The reinforcement component can be a fabric. The fabric can be formed from the fiber, as discussed herein. Examples of fabrics include, but are not limited to, stitched fabrics, woven fabrics, and combinations thereof. The fabric can be unidirectional, multiaxial, and combinations thereof. The reinforcement component can be a combination of the fiber and the fabric.

The prepreg is obtainable by impregnating the matrix component into the reinforcement component. Impregnating the matrix component into the reinforcement component may be accomplished by a variety of processes. The prepreg can be formed by contacting the reinforcement component and the matrix component via rolling, dipping, spraying, or other such procedures. After the prepreg reinforcement component has been contacted with the prepreg matrix component, the solvent can be removed via volatilization. While and/or after the solvent is volatilized the prepreg matrix component can be cured, e.g. partially cured. This volatilization of the solvent and/or the partial curing can be referred to as B-staging. The B-staged product can be referred to as the prepreg.

For some applications, B-staging can occur via an exposure to a temperature of 60° C. to 250° C.; for example B-staging can occur via an exposure to a temperature from 65° C. to 240° C. , or 70° C. to 230° C. For some applications, B-staging can occur for a period of time of 1 minute (min) to 60 min; for example B-staging can occur for a period of time from, 2 min to 50 min, or 5 min to 40 mins. However, for some applications the B-staging can occur at another temperature and/or another period of time. One or more of the prepregs may be cured (e.g. more fully cured) to obtain a cured product. The prepregs can be layered and/or formed into a shape before being cured further. For some applications (e.g. when an electrical laminate is being produced) layers of the prepreg can be alternated with layers of a conductive material. An example of the conductive material includes, but is not limited to, copper foil. The prepreg layers can then be exposed to conditions so that the matrix component becomes more fully cured.

One example of a process for obtaining the more fully cured product is pressing. One or more prepregs may be placed into a press where it subjected to a curing force for a predetermined curing time interval to obtain the more fully cured product. The press may have a curing temperature of 80° C. to 250° C.; for example the press may have a curing temperature of 85° C. to 240° C., or 90° C. to 230° C. For one or more embodiments, the press has a curing temperature that is ramped from a lower curing temperature to a higher curing temperature over a ramp time interval.

During the pressing, the one or more prepregs can be subjected to a curing force via the press. The curing force may have a value that is 10 kilopascals (kPa) to 350 kPa; for example the curing force may have a value that is 20 kPa to 300 kPa, or 30 kPa to 275 kPa. The predetermined curing time interval may have a value that is 5 s to 500 s; for example the predetermined curing time interval may have a value that is 25 s to 540 s, or 45 s to 520 s. For other processes for obtaining the cured product other curing temperatures, curing force values, and/or predetermined curing time intervals are possible. Additionally, the process may be repeated to further cure the prepreg and obtain the cured product.

For various embodiments, the cured products formed from the curable compositions of the present disclosure, as discussed herein, can have a glass transition temperature of at least 160° C.

For various embodiments, the cured products formed from the curable compositions of the present disclosure, as discussed herein, can have a dielectric constant in the range of 4 to 7 at a frequency of 1-30 GHz. All dielectric constants between 4 and 7 are included herein and are disclosed herein; for example, the dielectric constant can be 5, 6, 4.5, 5.5, 6.5, or 6.75.

For various embodiments, the cured products formed from the curable compositions of the present disclosure, as discussed herein, can have a dissipation factor of less than 0.01 at 1 GHz; for example, the dissipation factor at 1 GHz can be 0.003 to 0.01, or 0.004 to 0.007.

Examples of uses for printed circuit boards made using the cured products of this invention include but are not limited to microwaves, embedded smartphones, and servers.

### EXAMPLES

### Materials:

PROLOGIC™ HS8005 (H/R), a low dielectric constant and low dissipation factor epoxy/hardener system from the Dow Chemical Company

R-706 TiO2, from DuPont

Silane coupling agent from Dow Corning XIAMETER® OFS-6040

Catalyst, 2-ethyl-4-methyl imidazole from Sigma Aldrich

High-shear mixing processing

### Formulation

The HS8005 system is provided at 57 wt % (solids) in xylene. This is combined in various weight fractions with the DuPont R-706 to achieve a final solids ratio like those given in Table 1, for example, a formulation resulting in 10 wt % TiO2. Additionally, an adhesion promoter (e.g., XIAMETER® OFS-6040) is added at the 2 wt % level.

Seven hardener formulations were prepared and tested, along with two comparative samples. The formulations are depicted in Table 1, below. The formulations are listed as either XX %-1080 or XX %-2116. 1080 refers to a glass fabric with a weave pattern designated as 1080 which is common to the printed circuit board industry (e.g., JPS Composite Materials a JPS Industries Inc., produces a 1080 style glass with a warp count of 60 and a fill count of 47) and 2116 refers to a glass fabric with a weave pattern designated as 1080 which is common to the printed circuit board industry (e.g., JPS Composite Materials a JPS Industries Inc., produces a 1080 style glass with a warp count of 60 and a fill count of 58). ‘XX %’ refers to the weight percent of TiO₂.

TABLE 1
Formulations, Frequency, Dielectric
Constant, and Dissipation Factor

| Example | Formulation | Frequency (GHz) | Dk | Df |
|---|---|---|---|---|
| 1 | 10%-1080 | 7.08 | 3.701 | 0.0084 |
| 2 | 20%-1080 | 7.06 | 3.986 | 0.0086 |
| 3 | 30%-1080 | 7.06 | 4.568 | 0.0087 |
| 4 | 40%-1080 | 7.00 | 5.296 | 0.0091 |
| 5 | 50%-1080 | 7.02 | 6.297 | 0.0100 |
| 6 | 20%-2116 | 6.73 | 4.437 | 0.0079 |
| 7 | 40%-2116 | 6.60 | 5.316 | 0.0078 |
| Comparative A | 2116 | 6.83 | 3.674 | 0.0068 |
| Comparative B | 1080 | 7.08 | 3.276 | 0.0074 |

Single sheets of glass fabric were manually impregnated with varnish prepared with a high-speed mixer. The loading varnish was adjusted to produce sheets with about 70 wt % (varnish+filler) for the 1080 glass system and about 50 wt % (varnish+filler) in the 2116 glass system. The varnish coated glass was then subjected to a partial cure (B-staging) in a 170° C. oven for several minutes. The oven time was adjusted so that the remaining reactivity of the system was over 100 seconds. This remaining reactivity was used for the following lamination process. The partially cured sheets (prepregs) were stacked (2-4 ply) and then pressed at 200° C. under sufficient pressure to induce some flow and to ensure that air bubbles were expelled from the final laminate article. The laminate tested for copper peel strength performance. The results are shown in Table 2.

TABLE 2
Copper Peel Strength Performance Study

| Formulation | Copper Peel Strength (lb/in) |
|---|---|
| 30% TiO2, no additives | 2.35 |
| 30% TiO2, 2% Silane | 3.57 |
| 30% TiO2, 2% Silane, 220° C. Cure | 3.75 |
| 33% TiO2, 4% Silane, 220° C. Cure | 3.98 |
| 33% TiO2, 5% Silane, 220° C. Cure | 3.90 |

### Test Methods

### Dielectric Constant (Dk)

The dielectric constant of respective 0.3 millimeter (mm) thick samples of the cured products was determined by ICP TM-650 2.5.5.13 Dielectric Constant & Loss Tangent standard measurement method employing an Agilent E4991A RF impedance/material analyzer.

### Dissipation Factor (Df)

The dissipation factor of respective 0.3 mm thick samples of the cured products was determined by ASTM D-150 employing an Agilent E4991A RF impedance/material analyzer.

### Copper Peel Strength (CPS)

Copper peel strength was measured using an IMASS SP-2000 slip/peel tester equipped with a variable angle peel fixture capable of maintaining the desired 90° peel angle throughout the test. For the copper etching, 2″×4″ copper clad laminates were cut. Two strips of ¼″ graphite tape were placed lengthwise along the sample on both faces of the laminate with at least a ½″ space between them. The laminate pieces were then placed in a KeyPro bench top etcher. Once the samples were removed from the etcher and properly dried, the graphite tape was removed to reveal the copper strips. A razor blade was used to pull up ½ of each copper strip. The laminate was then loaded onto the IMASS tester. The copper strip was clamped and the copper peel test was conducted at a 90° angle with a pull rate of 2.8 in/min.

What is claimed is:

1. A curable composition, comprising:
a) an epoxy resin; and
b) a hardener compound for curing with the epoxy resin, the hardener compound comprising:
a terpolymer having a first constitutional unit of the formula (I): 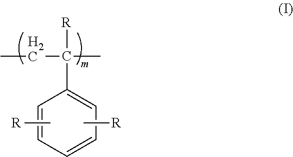
a second constitutional unit of the formula (II): 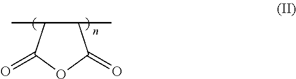
and a third constitutional unit of the formula (III): 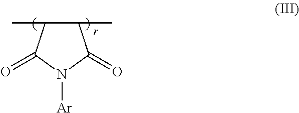
where each m, n and r is independently a real number that represents a mole fraction of the respective constitutional unit in the terpolymer, each R is independently a hydrogen, an aromatic group or an aliphatic group, Ar is an aromatic radical, and where the epoxy group to the second constitutional unit has a molar ratio in a range of 1.0:1.0 to 2.7:1.0; and
c) titanium dioxide.

2. The curable composition of claim 1, further comprising
d) a coupling agent selected from the group consisting of organofunctional silanes and polymeric adhesion promoters.

3. The curable composition of claim 1, further comprising a catalyst selected from the group consisting of 2-methyl imidazole (2MI), 2-phenyl imidazole (2PI), 2-ethyl-4-methyl imidazole (2E4MI), 1-benzyl-2-phenylimidazole (1B2PZ), boric acid, triphenylphosphine (TPP), tetraphenylphosphonium-tetraphenylborate (TPP-k) and combinations thereof.

4. (Orginal) The curable composition of claim 1 wherein the titanium dioxide is in a rutile crystal phase.

5. (Orginal) The curable composition of claim 1, where the epoxy group to the second constitutional unit has a molar ratio in a range of 1.1:1.0 to 1.9:1.0.

6. The curable composition of claim 1, where the epoxy group to the second constitutional unit has a molar ratio in a range of 1.3:1.0 to 1.7:1.0.

7. The curable composition of claim 1, where a cured product of the curable composition has a glass transition temperature of at least 160° C.

8. The curable composition of claim 1, where a cured product of the curable composition has a dielectric constant (Dk) in the range of from 4 to 7 at a frequency of 1-30 GHz.

9. The curable composition of claim 1, where a cured product of the curable composition has a dissipation factor (D_{f}) of 0.01 or less at a frequency of 1 GHz.

10. The curable composition of claim 1, where each R is independently a hydrogen, an aromatic group or an aliphatic group, and Ar is a group representing a monocyclic or a polycyclic aromatic or heteroaromatic ring.

11. The curable composition of claim 1, where the first constitutional unit to the second constitutional unit has a molar ratio in a range of 1:1 to 20:1.

12. The curable composition of claim 1, where the second constitutional unit constitutes 0.1 percent (%) to 41% by weight of the terpolymer.

13. The curable composition of claim 1, where the third constitutional unit constitutes 0.1% to 62.6 9% by weight of the terpolymer.

14. The curable composition of claim 1, where the epoxy resin is selected from the group consisting of aromatic epoxy compounds, alicyclic epoxy compounds, aliphatic epoxy compounds, and combinations thereof.

15. A prepreg prepared from the curable composition of claim 1.

16. An electrical laminate prepared from the curable composition of claim 1.

17. A method of preparing a curable composition, comprising:
a) providing an epoxy resin; and
b) reacting the epoxy resin with a hardener compound, the hardener compound comprising:
a terpolymer having a first constitutional unit of the formula (I): 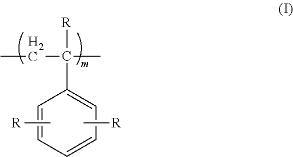
a second constitutional unit of the formula (II): 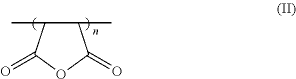
and a third constitutional unit of the formula (III): 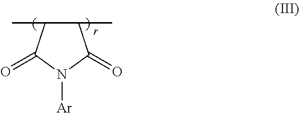
where each m, n and r is independently a real number that represents a mole fraction of the respective constitutional unit in the terpolymer, each R is independently a hydrogen, an aromatic group or an aliphatic group, Ar is an aromatic radical, and where the epoxy group to the second constitutional unit has a molar ratio in a range of 1.0:1.0 to 2.7:1.0 to form an epoxy/hardener admixture; and
c) incorporating titanium dioxide into the epoxy/hardener admixture.

19. The prepreg of claim 15, wherein the prepreg further comprises a reinforcement component.

20. The electrical laminate of claim 16 wherein the electrical laminate possesses a dielectric constant of 4 to about 7 at a frequency of 1-30 GHz and a dissipation factor of less than 0.01 at 1 GHz.
